(19) United States
(12) Patent Application Publication
(10) Pub. No.: US 2025/0159892 A1
(43) Pub. Date: May 15, 2025

(54) SEMICONDUCTOR DEVICE AND MANUFACTURING METHOD OF THE SEMICONDUCTOR DEVICE

(71) Applicant: SK hynix Inc., Icheon-si Gyeonggi-do (KR)

(72) Inventor: Jae Ho KIM, Icheon-si Gyeonggi-do (KR)

(73) Assignee: SK hynix Inc., Icheon-si Gyeonggi-do (KR)

(21) Appl. No.: 18/436,289

(22) Filed: Feb. 8, 2024

(30) Foreign Application Priority Data
Nov. 13, 2023 (KR) 10-2023-0156341

(51) Int. Cl. H10B 43/30; H10B 41/30; H10B 41/50; H10B 43/50

(52) U.S. Cl. CPC H10B 43/30; H10B 41/30; H10B 41/50; H10B 43/50

(57) ABSTRACT

A semiconductor device according to an embodiment of the present disclosure includes an upper line including an opening, a lower line positioned below the upper line and overlapping with the opening in a first direction, and an auxiliary line positioned below the lower line and overlapping with the opening in the first direction, wherein the auxiliary line contacts a lower surface of the lower line.

### CROSS-REFERENCE TO RELATED APPLICATION

The present application claims priority under 35 U.S.C. § 119(a) to Korean patent application number 10-2023-0156341 filed on Nov. 13, 2023, in the Korean Intellectual Property Office, the entire disclosure of which is incorporated by reference herein.

### BACKGROUND

### 1. Technical Field

Various embodiments of the present disclosure generally relate to a semiconductor device and a manufacturing method of the semiconductor device, and more particularly, to a semiconductor device including line structures and a method of the semiconductor device.

### 2. Related Art

A semiconductor device may include a non-volatile memory device in which stored data is retained even when power supply is interrupted. The non-volatile memory device may be classified into a two-dimensional structure or a three-dimensional structure according to a structure in which memory cells are arranged. Memory cells of a non-volatile memory device having a two-dimensional structure may be arranged in a single layer on a substrate, and memory cells of a non-volatile memory device having a three-dimensional structure may be stacked in a vertical direction on the substrate. Since a degree of integration of the non-volatile memory device having the three-dimensional structure is higher than that of the non-volatile memory device having the two-dimensional structure, electronic devices using non-volatile memory devices having a three-dimensional structure have recently been increasing.

A semiconductor device may include line structures that perform various functions, such as applying electrical signals to memory cells or supplying power to peripheral circuits.

### SUMMARY

According to an embodiment, a semiconductor device may include an upper line including an opening, a lower line positioned below the upper line and overlapping with the opening in a first direction, and an auxiliary line positioned below the lower line and overlapping with the opening in the first direction, wherein the auxiliary line contacts a lower surface of the lower line.

According to an embodiment, a method of manufacturing a semiconductor device may include forming a lower line, forming an auxiliary line under the lower line, the auxiliary line contacting a portion of the lower surface of the lower line, forming an upper line over the lower line, and forming an opening by etching a portion of the upper line, the opening overlapping with the lower line and the auxiliary line.

### BRIEF DESCRIPTION OF THE DRAWINGS

FIG. 1 is a diagram illustrating a semiconductor device according to an embodiment of the present disclosure;

FIGS. 2A and 2B are diagrams illustrating a structure of a semiconductor device including line structures according to an embodiment of the present disclosure;

FIGS. 3A to 3G are diagrams illustrating a method of manufacturing a semiconductor device including line structures according to an embodiment of the present disclosure;

FIGS. 4 and 5 are diagrams illustrating various examples of a semiconductor device including line structures according to an embodiment of the present disclosure;

FIG. 6 is a diagram illustrating a memory card system to which a memory device according to the embodiment of the present disclosure is applied; and

FIG. 7 is a diagram illustrating a solid state drive (SSD) system to which a memory device according to the embodiment of the present disclosure is applied.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Hereinafter, embodiments of the present disclosure will be described in detail with reference to the accompanying drawings in order for those skilled in the art to be able to readily implement the technical spirit of the present disclosure.

Various embodiments relate to a semiconductor device capable of reducing defects in a line structure and a method of manufacturing the semiconductor device.

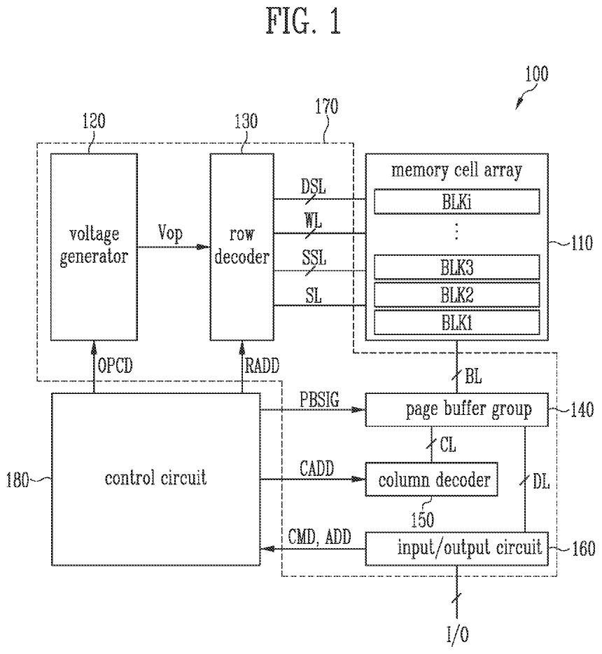

FIG. 1 is a diagram illustrating a semiconductor device according to an embodiment of the present disclosure.

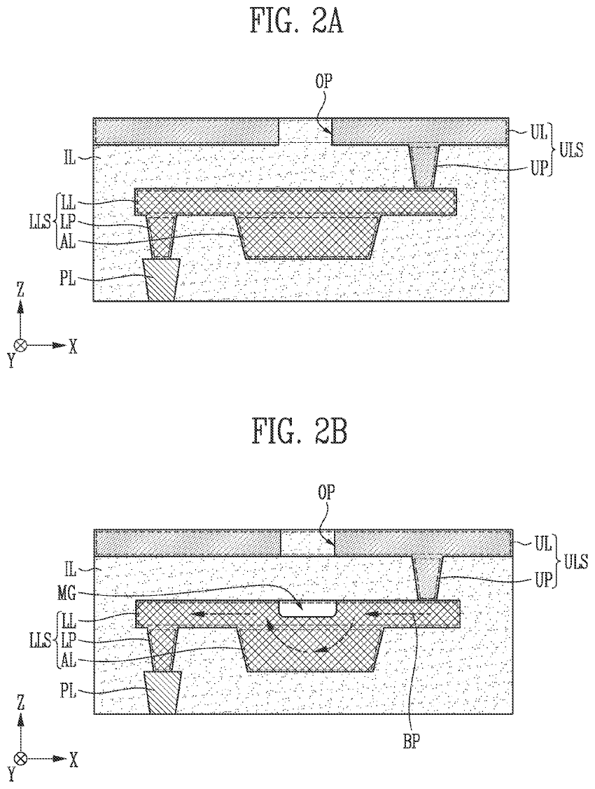

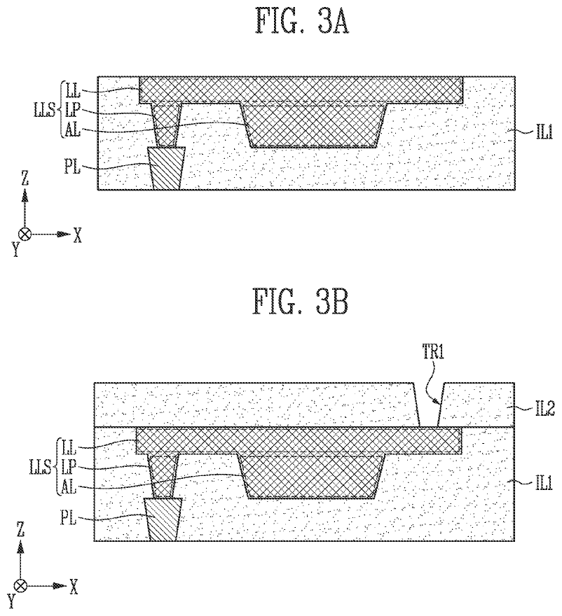

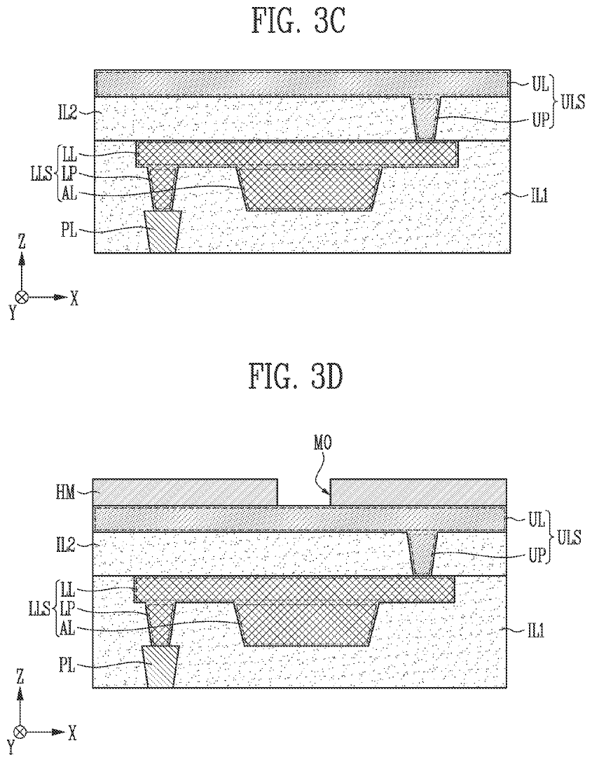

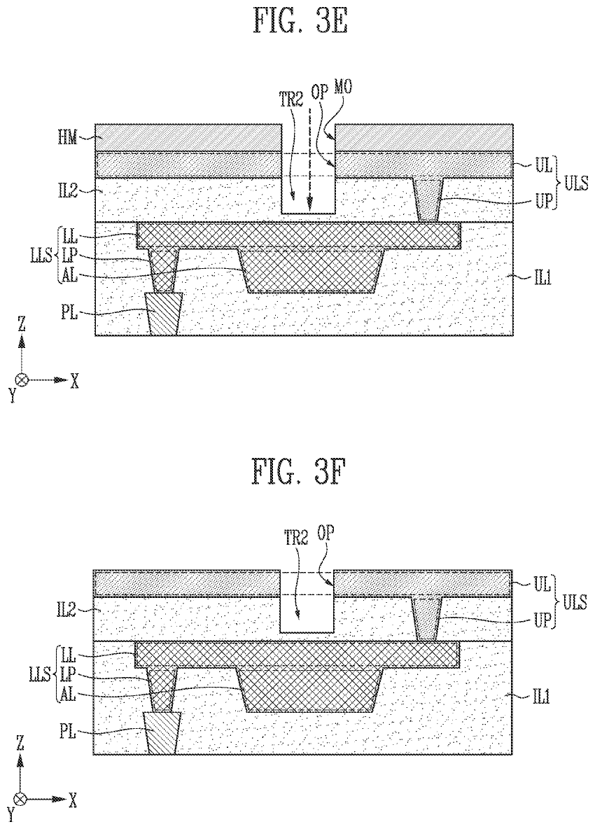

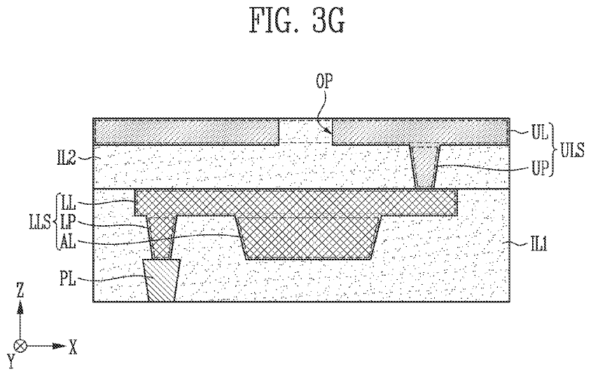

In the present disclosure, the semiconductor device may be a memory device 100. Referring to FIGS. 1 to 7, it may be described on the assumption that the semiconductor device is the memory device 100. However, a semiconductor device including the features of line structures to be described below in FIGS. 2A, 2B, and 3A to 3D may be a non-memory device.

Referring to FIG. 1, the memory device 100 may include a memory cell array 110, a peripheral circuit 170, and a control circuit 180.

The memory cell array 110 may include first to ith memory blocks BLK1 to BLKi. Each of the first to ith memory blocks BLK1 to BLKi may include memory cells capable of storing data. Drain select lines DSL, word lines WL, source select lines SSL, and a source line SL may be coupled to each of the first to ith memory blocks BLK1 to BLKi, and bit lines BL may be commonly coupled to the first to ith memory blocks BLK1 to BLKi.

The first to ith memory blocks BLK1 to BLKi may be formed in a two-dimensional structure or a three-dimensional structure. The memory blocks having the two-dimensional structure may include memory cells arranged in a single layer on a substrate. The memory blocks having the three-dimensional structure may include memory cells stacked in a vertical direction on the substrate.

The memory cells may store one-bit or two-or-more-bit data according to a program method. For example, a method in which one-bit data is stored in one memory cell is referred to as a single level cell (SLC) method, and a method in which two-bit data is stored in one memory cells is referred to as a multi-level cell (MLC) method. A method in which three-bit data is stored in one memory cell is referred to as a triple level cell (TLC) method, and a method in which four-bit data is stored in one memory cell is referred to as a quad level cell (QLC) method. In addition, five-or-more-bit data may be stored in one memory cell.

The peripheral circuit 170 may be configured to perform a program operation for storing data, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop used for a program operation, a read operation, or an erase operation in response to an operation code OPCD. For example, the voltage generator 120 may be configured to generate program voltages, turn-on voltages, turn-off voltages, negative voltages, pre-charge voltages, verify voltages, read voltages, pass voltages, or erase voltages in response to the operation code OPCD. The operating voltages Vop generated by the voltage generator 120 may be applied to the drain select lines DSL, the word lines WL, the source select lines SSL, and the source line SL of a selected memory block through the row decoder 130.

The program voltages may be applied to a selected word line among the word lines WL during a program operation, and may be used to increase threshold voltages of memory cells coupled to the selected word line. The turn-on voltages may be applied to the drain select lines DSL or the source select lines SSL and may be used to turn on drain select transistors or source select transistors. The turn-off voltages may be applied to the drain select lines DSL or the source select lines SSL and may be used to turn off the drain select transistors or the source select transistors. For example, the turn-off voltages may be set to 0V. The pre-charge voltages may be higher than 0V and may be applied to the bit lines during a read operation. The verify voltages may be used during a verify operation for determining whether threshold voltages of selected memory cells have been increased to a target level. The verify voltages may be set to various levels according to the target level and may be applied to the selected word line.

The read voltages may be applied to the selected word line during a read operation of the selected memory cells. For example, the read voltages may be set to various levels according to a program method of the selected memory cells. The pass voltages may be applied to unselected word lines among the word lines WL during a program or read operation and may be used to turn on memory cells coupled to the unselected word lines. The erase voltages may be used during an erase operation for erasing the memory cells included in the selected memory block and may be applied to the source line SL.

The row decoder 130 may be configured to transfer the operating voltages Vop to the drain select lines DSL, the word lines WL, the source select lines SSL, and the source line SL that are coupled to the selected memory block according to a row address RADD. For example, the row decoder 130 may be coupled to the voltage generator 120 through global lines and may be coupled to the first to ith memory blocks BLK1 to BLKi through the drain select lines DSL, the word lines WL, the source select lines SSL, and the source line SL.

The page buffer group 140 may include page buffers (not shown) respectively coupled to the first to ith memory blocks BLK1 to BLKi. Each of the page buffers (not shown) may be coupled to the first to ith memory blocks BLK1 to BLKi through the bit lines BL. During a read operation, the page buffers (not shown) may sense a current or a voltage of the bit lines BL that varies according to the threshold voltages of the selected memory cells and may temporarily store sensed data in response to page buffer control signals PBSIG.

The column decoder 150 may be configured to transfer data between the page buffer group 140 and the input/output circuit 160 in response to a column address CADD. For example, the column decoder 150 may be coupled to the page buffer group 140 through column lines CL and may transfer enable signals through the column lines CL. The page buffers (not shown) included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transfer a command CMD and an address ADD that are received from an external controller to the control circuit 180 through the input/output lines I/O and may transfer data received from the external controller to the page buffer group 140 through the input/output lines I/O. Alternatively, the input/output circuit 160 may output data transferred from the page buffer group 140 to the external controller through the input/output lines I/O.

The control circuit 180 may output at least one of the operation code OPCD, the row address RADD, the page buffer control signals PBSIG, and the column address CADD in response to the command CMD and the address ADD. For example, when the command CMD input to the control circuit 180 corresponds to a program operation, the control circuit 180 may control the peripheral circuit 170 to perform a program operation of a memory block selected by the address ADD. When the command CMD that is input to the control circuit 180 corresponds to a read operation, the control circuit 180 may control the peripheral circuit 170 to perform the read operation of the memory block selected by the address ADD and output read data. When the command CMD that is input to the control circuit 180 corresponds to an erase operation, the control circuit 180 may control the peripheral circuit 170 to perform the erase operation of the selected memory block.

FIGS. 2A and 2B are diagrams illustrating a structure of a semiconductor device including line structures according to an embodiment of the present disclosure.

In the present disclosure, the semiconductor device (for example, the memory device 100 of FIG. 1) may include an upper line structure ULS and a lower line structure LLS. The upper line structure ULS and the lower line structure LLS may be formed in the semiconductor device (for example, the memory device 100 of FIG. 1). The upper line structure ULS and the lower line structure LLS may be coupled to at least one of the memory cell array 110, the peripheral circuit 170, and the control circuit 180 of FIG. 1. For example, the upper line structure ULS and the lower line structure LLS may transfer electrical signals applied from the peripheral circuit 170 to at least one memory cell included in the memory cell array 110. Alternatively, the upper line structure ULS and the lower line structure LLS may be used to supply power to the peripheral circuit 170. Alternatively, the upper line structure ULS and the lower line structure LLS may electrically couple the peripheral circuit 170 to the control circuit 180. In addition, the upper line structure ULS and the lower line structure LLS may be used to perform various functions. Hereinafter, the structure of the upper line structure ULS and the lower line structure LLS that are included in the semiconductor device according to the present disclosure will be described.

Referring to FIG. 2A, the semiconductor device may include the upper line structure ULS and the lower line structure LLS. The upper line structure ULS may be located on the lower line structure LLS. The upper line structure ULS may be exposed to an uppermost part of the semiconductor device or may be located within a predetermined distance from the uppermost part of the semiconductor device. The lower line structure LLS may be located under the upper line structure ULS and may contact the upper line structure ULS.

The upper line structure ULS may include an upper line UL. The upper line structure ULS may further include an upper plug UP. The lower line structure LLS may include a lower line LL and an auxiliary line AL. The lower line structure LLS may further include a lower plug LP. The lower plug LP may contact a target plug PL. The target plug PL may be a peripheral circuit contact plug coupled to the peripheral circuit 170 shown in FIG. 1. The upper line structure ULS, the lower line structure LLS, and the target plug PL may be electrically coupled to each other. The upper line structure ULS, the lower line structure LLS, and the target plug PL may contact an insulating layer IL. For example, at least a portion of the upper line structure ULS may be formed in the insulating layer IL. Also, the lower line structure LLS may be formed in the insulating layer IL.

The upper line UL may include an opening OP. The opening OP may be an area of the upper line UL from which a part is removed. The opening OP may be filled with the insulating layer IL.

The upper plug UP may protrude downwards from the upper line UL. The upper plug UP may contact the lower line LL. For example, the upper plug UP may contact an upper surface of the lower line LL. The upper plug UP may electrically couple the upper line UL to the lower line LL.

The upper line UL and the upper plug UP may be formed integrally and simultaneously. For example, the upper line UL and the upper plug UP may be formed through a damascene process. The upper line UL and the upper plug UP may include the same material. For example, the upper line UL and the upper plug UP may include aluminum (Al).

The lower line LL may overlap with the opening OP of the upper line UL. The lower line LL may include an area that overlaps with the opening OP. A portion of the lower line LL may overlap with the opening OP.

The auxiliary line AL may overlap with the opening OP of the upper line UL. The auxiliary line AL may include an area that overlaps with the opening OP. A portion of the auxiliary line AL may overlap with the opening OP. For example, a planar area of the auxiliary line AL may be greater than that of the opening OP in the upper line UL. In another example, a width (e.g., a width in an X direction and a width in a Y direction) of the auxiliary line AL may be greater than a width (e.g., a width in the X direction and a width in the Y direction) of the opening OP in the upper line UL.

The auxiliary line AL may contact a lower surface of the lower line LL. For example, the auxiliary line AL may contact a portion of the lower surface of the lower line LL. The lower line LL may include an area that overlaps with the auxiliary line AL. For example, a portion of the lower line LL may overlap with the auxiliary line AL.

The lower plug LP may protrude downwards from the lower line LL. The lower plug LP may contact the target plug PL. For example, the lower plug LP may contact the upper surface of the target plug PL. The lower plug LP may electrically couple the lower line LL to the target plug PL.

The auxiliary line AL and the lower plug LP may be located under the lower line LL (e.g., an opposite direction to the Z direction). For example, the auxiliary line AL and the lower plug LP may be located at the same level (e.g., a position on a Z-axis). The auxiliary line AL and the lower plug LP may have the same depth or may have different depths.

The lower line LL, the auxiliary line AL, and the lower plug LP may be formed integrally and simultaneously. For example, the lower line LL, the auxiliary line AL, and the lower plug LP may be formed through a damascene process. The lower line LL, the auxiliary line AL, and the lower plug LP may include the same material. For example, the lower line LL, the auxiliary line AL, and the lower plug LP may include copper (Cu).

Referring to FIG. 2A, the upper plug UP and the lower plug LP may be located on opposite sides of the auxiliary line AL in the X direction. That is, the auxiliary line AL may be located between the upper plug UP and the lower plug LP in the X direction. For example, the upper plug UP may be formed in the +X direction from the auxiliary line AL, and the lower plug LP may be formed in the −X direction from the auxiliary line AL.

Therefore, the auxiliary line AL and the lower line LL, together, may form a current path. For example, electrical signals applied from the upper line UL may be transferred to the lower line LL and the auxiliary line AL through the upper plug UP. Also, the electrical signals that are transferred to the lower line LL and the auxiliary line AL may be transferred to the target plug PL through the lower plug LP. In another example, electrical signals applied from the target plug PL may be transferred to the lower line LL and the auxiliary line AL through the lower plug LP. In addition, electrical signals that are transferred to the lower line LL and the auxiliary line AL may be transferred to the upper line UL through the upper plug UP.

FIG. 2B shows a bypass (BP) that is formed in the lower line structure LLS when a defect occurs during the operation of the semiconductor device. A defect may occur in a first region MG of the lower line LL while the semiconductor device is operating. The first region MG may overlap with the opening OP of the upper line UL. For example, the first region MG may include an area that overlaps with the opening OP.

At least a portion of the first region MG in the lower line LL may include a defect. The defect may be a migration of a material that is included in the lower line LL (e.g., copper). For example, while a part of the upper line UL is etched to include the opening OP, stress may be imposed on the lower line LL. The migration of the material in the first region MG (e.g., copper) may occur due to the stress imposed on the lower line LL.

When a defect occurs in the first region MG of the lower line LL, such as migration, a resistance may increase, or a short circuit may occur in the lower line LL. However, according to an embodiment of the present disclosure, since the semiconductor device includes the auxiliary line AL that contacts the lower surface of the lower line LL, the bypass BP may be formed in the lower line structure LLS. Referring to FIG. 2B, the auxiliary line AL may overlap with the first region MG and may serve as a bypass for the defect that occurs in the first region MG. For example, even when a defect occurs in the first region MG, the upper plug UP and the lower plug LP may be electrically coupled to each other through the bypass BP that is formed along the lower line LL and the auxiliary line AL.

The first region MG, shown on FIG. 2B, may be one of many examples. In another example, the planar area of the first region MG may be smaller or greater, and the depth of the first region MG may be smaller or greater.

FIGS. 3A to 3G are diagrams illustrating a method of manufacturing a semiconductor device including line structures according to an embodiment of the present disclosure.

Referring to 3A, the lower line structure LLS may be formed in a first insulating layer IL1. The lower line LL and the auxiliary line AL that contacts a part of the lower surface of the lower line LL may be formed in the first insulating layer IL1. Additionally, the lower plug LP that protrudes downwards from the lower line LL and contacts the target plug PL may also be formed simultaneously in the first insulating layer IL1.

The lower line structure LLS may be formed integrally. The lower line LL, the auxiliary line AL, and the lower plug LP may be formed through a damascene process. For example, the lower line structure LLS may be formed by etching a portion of the first insulating layer IL1 and subsequently filling the corresponding area with a conductive material (e.g., copper).

Referring to FIG. 3B, a second insulating layer IL2 may be formed on the first insulating layer IL1 and the lower line structure LLS. The first insulating layer IL1 and the second insulating layer IL2 may include the same material or different materials. A first trench TR1 may be formed by etching a portion of the second insulating layer IL2. The first trench TR1 may expose a portion of the upper surface of the lower line LL.

Referring to FIG. 3C, the upper line structure ULS may be formed on the lower line structure LLS. The upper line structure ULS may include a conductive material (e.g., aluminum) that is formed on the second insulating layer IL2. The upper line UL may be located on the lower line LL. The upper plug UP may protrude downwards from the upper line UL and may be coupled to the lower line LL. The conductive material filling the first trench TR1 of the second insulating layer IL2 may correspond to the upper plug UP. The upper line UL may be coupled to the lower line LL through the upper plug UP.

Referring to FIG. 3D, a hard mask HM may be formed on the upper line UL. The hard mask HM may include a mask opening MO. The mask opening MO may overlap with the upper line UL, the lower line LL, and the auxiliary line AL.

Referring to FIG. 3E, the upper line UL and the second insulating layer IL2 may be etched along the mask opening MO. By etching the hard mask HM, the upper line UL and the second insulating layer IL2 may be etched to form a second trench TR2. The second trench TR2 may penetrate the upper line UL. A portion of the upper line UL may be etched to form the opening OP. Also, the second trench TR2 may expose a portion of the second insulating layer IL2. The second trench TR2 may be formed by using a dry etching process that uses reactive ions to etch a predetermined area.

The second trench TR2 may overlap with the lower line LL. Therefore, when an etching process (e.g., reactive ion dry etching) of forming the second trench TR2 is ongoing, stress may be imposed on the lower line LL. However, as describe above with reference to FIG. 2B, the second trench TR2 may also overlap with the auxiliary line AL. Therefore, even when the lower line LL to which the stress is applied may include a defect, the bypass BP may be formed and a short circuit of the lower line structure LLS may be avoided.

Referring to FIG. 3F, the hard mask HM of the upper line UL may be eliminated. A portion of the second trench TR2 that penetrates the upper line UL may be understood as the opening OP.

Referring to FIG. 3G, the second trench TR2 may be filled with an insulating material. As the insulating material fills in the second trench TR2, the opening OP may be filled with the insulating material.

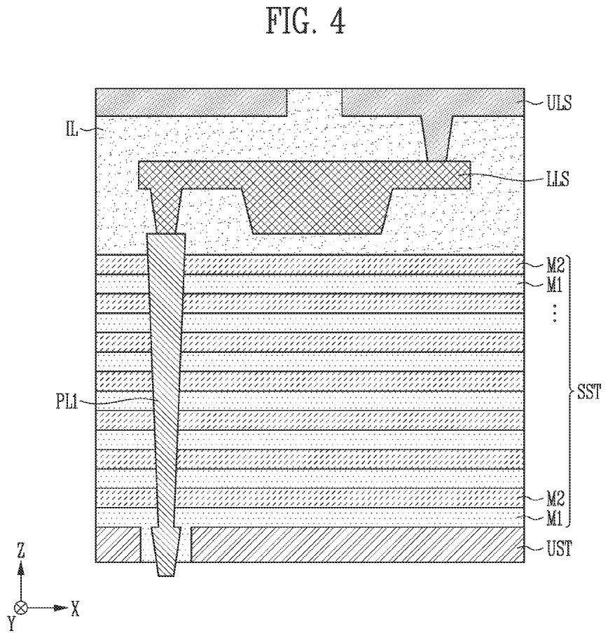

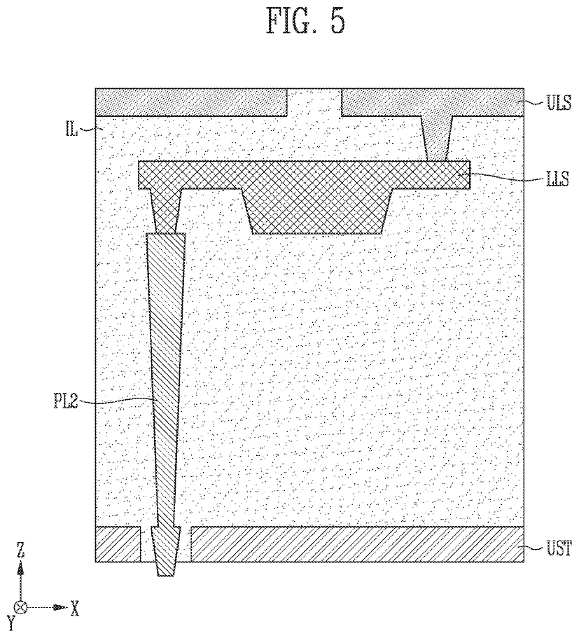

FIGS. 4 and 5 are diagrams illustrating various examples of a semiconductor device including line structures according to an embodiment of the present disclosure. In FIGS. 4 and 5, descriptions of structures overlapping with those shown in FIGS. 2A and 2B will be omitted or simplified.

Referring to FIGS. 4 and 5, the semiconductor device may include a lower structure UST that is located under the upper line structure ULS and the lower line structure LLS. A target plug PL1 or PL2 may penetrate the lower structure UST. In addition, the semiconductor device may include a peripheral circuit (for example, the peripheral circuit 170 of FIG. 1) that is located under the lower structure UST. The target plug PL1 or PL2 may be coupled to the peripheral circuit. For example, the target plug PL1 or PL2 may be a peripheral circuit contact plug that is electrically coupled to the peripheral circuit.

The target plug PL1 or PL2 may contact the lower plug LP of the lower line structure LLS. The target plug PL1 or PL2 may be electrically coupled to the lower line LL and the auxiliary line AL through the lower plug LP. The target plug PL1 or PL2 may be electrically coupled to the upper line UL through the lower line LL and the auxiliary line AL.

Referring to FIG. 4, the semiconductor device may further include a stacked structure SST. The stacked structure SST may be located on the lower structure UST. The stacked structure SST may be located under the upper line structure ULS and the lower line structure LLS. The stacked structure SST may include first material layers M1 and second material layers M2 that are alternately stacked. The first material layers M1 may be oxide layers, and the second material layers M2 may be nitride layers. The target plug PL1 may penetrate the stacked structure SST. The target plug PL1 may contact the peripheral circuit that is located under the lower structure UST by penetrating the first material layers M1 and the second material layers M2.

Referring to FIG. 5, the target plug PL2 might not penetrate the stacked structure SST. For example, the target plug PL2 may be located in an area in which the insulating layer IL is formed to a predetermined height (e.g., a height corresponding to the height of the stacked structure SST in FIG. 4) in the semiconductor device. Although the target plug PL1 in FIG. 4 is spaced apart from the target plug PL2 in FIG. 5, the lower line structure LLS may also contact the target plug PL2 in FIG. 5.

Aside from the target plug PL1 and the target plug PL2, shown in FIG. 4 and FIG. 5, the upper line structure ULS and the lower line structure LLS may be coupled to various types of target plugs. That is, the upper line structure and the lower line structure may be included in the scope of the present disclosure as long as the upper and lower line structures satisfy the specifications described above in FIGS. 2A and 2B.

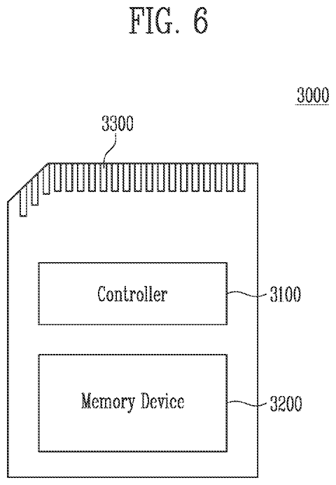

FIG. 6 is a diagram illustrating a memory card system 3000 to which a memory device of the present disclosure is applied.

Referring to FIG. 6, the memory card system 3000 may include a controller 3100, a memory device 3200, and a connector 3300.

The controller 3100 may be coupled to the memory device 3200. The controller 3100 may be configured to access the memory device 3200. For example, the controller 3100 may control a program operation, a read operation or an erase operation, or a background operation of the memory device 3200. The controller 3100 may be configured to provide an interface between the memory device 3200 and a host. The controller 3100 may be configured to drive firmware for controlling the memory device 3200. For example, the controller 3100 may include components, such as a Random Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. For example, the controller 3100 may be configured to communicate with the external device through at least one of various communication protocols, such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be defined by at least one of the above-described communication protocols.

The memory device 3200 may include a plurality of memory cells and may be configured in the same manner as the memory device 100 shown in FIG. 1.

The controller 3100 and the memory device 3200 may be integrated into a single semiconductor device to constitute a memory card. For example, the controller 3100 and the memory device 3200 may constitute a memory card, such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro, or eMMC), an SD card (SD, miniSD, microSD, or SDHC), and a Universal Flash Storage (UFS).

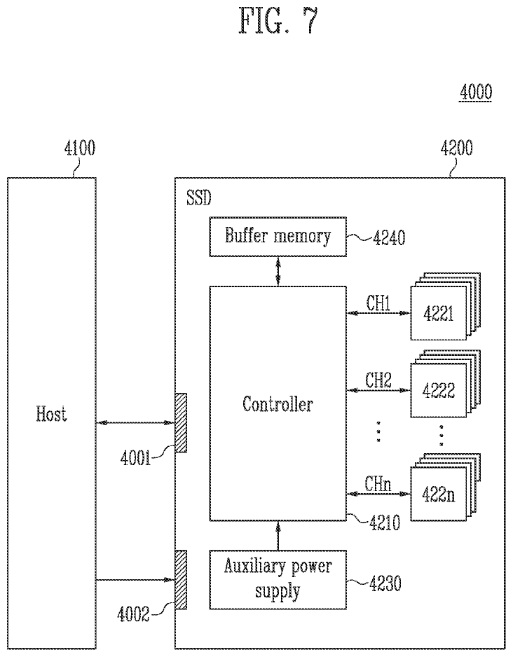

FIG. 7 is a diagram illustrating solid state drive (SSD) system 4000 to which the memory device of the present disclosure is applied.

Referring to FIG. 7, an SSD system 4000 may include a host 4100 and a SSD 4200. The SSD 4200 may exchange a signal with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. For example, the signal may be a signal based on an interface between the host 4100 and the SSD 4200. For example, the signal may be defined by at least one of interfaces, such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), an Integrated Drive Electronics (IDE), Firewire, Universal Flash Storage (UFS), WI-FI, Bluetooth, and NVMe interfaces.

The plurality of memory devices 4221 to 422n may include a plurality of memory cells configured to store data. Each of the plurality of memory devices 4221 to 422n may be configured in the same manner as the memory device 100 shown in FIG. 1. The plurality of memory devices 4221 to 422n may communicate with the controller 4210 through channels CH1 to CHn.

The auxiliary power supply 4230 may be coupled to the host 4100 through a power connector 4002. The auxiliary power supply 4230 may receive power input from the host 4100 and charge the power. When the supply of power from the host 4100 is not smooth, the auxiliary power supply 4230 may provide power for the SSD 4200. For example, the auxiliary power supply 4230 may be located inside or outside of the SSD 4200. For example, the auxiliary power supply 4230 may be located on a main board and provide auxiliary power to the SSD 4200.

The buffer memory 4240 may serve as a buffer memory of the SSD 4200. For example, the buffer memory 4240 may temporarily store data received from the host 4100 or data received from the plurality of memory devices 4221 to 422n, or may temporarily store metadata (e.g., mapping tables) of the memory devices 4221 to 422n. The buffer memory 4240 may include volatile memories, such as DRAM, SDRAM, DDR SDRAM, and LPDDR SDRAM, or non-volatile memories such as FRAM, ReRAM, STT-MRAM, and PRAM.

According to embodiments of the present disclosure, a defect in a line structure may be reduced by changing a structure of the line structure.

What is claimed is:

1. A semiconductor device, comprising:
an upper line including an opening;
a lower line positioned below the upper line and overlapping with the opening in a first direction; and
an auxiliary line positioned below the lower line and overlapping with the opening in the first direction, wherein the auxiliary line contacts a lower surface of the lower line.

2. The semiconductor device of claim 1, wherein the auxiliary line contacts a portion of the lower surface of the lower line.

3. The semiconductor device of claim 1, wherein a planar area of the auxiliary line is greater than a planar area of the opening in the upper line.

4. The semiconductor device of claim 1, wherein a width of the auxiliary line in a second direction intersecting the first direction is greater than a width of the opening in the upper line in the second direction.

5. The semiconductor device of claim 1, further comprising:
an upper plug protruding downwards from the upper line and contacting the lower line; and
a lower plug protruding downwards from the lower line and contacting a target plug.

6. The semiconductor device of claim 5, wherein the upper plug and the lower plug are located on opposite sides of the auxiliary line in a second direction intersecting the first direction.

7. The semiconductor device of claim 6, wherein the auxiliary line is located between the upper plug and the lower plug in the second direction.

8. The semiconductor device of claim 1, wherein the auxiliary line and the lower line, together, form a current path.

9. The semiconductor device of claim 1, wherein the lower line and the auxiliary line include the same material.

10. The semiconductor device of claim 9, wherein the lower line and the auxiliary line include copper (Cu).

11. The semiconductor device of claim 1, further comprising a stacked structure located under the upper line, the lower line, and the auxiliary line, wherein the stacked structure includes first material layers and second material layers, which are alternately stacked.

12. The semiconductor device of claim 11, further comprising a target plug penetrating the stacked structure.

13. The semiconductor device of claim 12, wherein the target plug is electrically coupled to the upper line through the lower line and the auxiliary line.

14. The semiconductor device of claim 12, further comprising a peripheral circuit located under the stacked structure.

15. The semiconductor device of claim 14, wherein the target plug is electrically coupled to the peripheral circuit.
